(19) United States
(12) Patent Application Publication
(10) Pub. No.: US 2025/0087623 A1
(43) Pub. Date: Mar. 13, 2025

(54) PACKAGED SEMICONDUCTOR DEVICE HAVING IMPROVED RELIABILITY AND INSPECTIONABILITY AND MANUFACTURING METHOD THEREOF

(71) Applicant: STMICROELECTRONICS S.r.l., Agrate Brianza (IT)

(72) Inventor: Agatino MINOTTI, Mascalucia (IT)

(73) Assignee: STMICROELECTRONICS S.r.l., Agrate Brianza (IT)

(21) Appl. No.: 18/956,979

(22) Filed: Nov. 22, 2024

Related U.S. Application Data
(62) Division of application No. 17/472,207, filed on Sep. 10, 2021, now Pat. No. 12,183,707.

(30) Foreign Application Priority Data
Sep. 14, 2020 (IT) 102020000021679

(51) Int. Cl. H01L 23/00; H01L 23/538

(52) U.S. Cl. CPC H01L 24/73; H01L 23/5389; H01L 24/24; H01L 24/25; H01L 24/92; H01L 24/97; H01L 24/32; H01L 2224/24226; H01L 2224/24247; H01L 2224/244; H01L 2224/2501; H01L 2224/32225; H01L 2224/73267; H01L 2224/92244; H01L 2224/97; H01L 2924/15153

(57) ABSTRACT

Packaged device having a carrying base; an accommodation cavity in the carrying base; a semiconductor die in the accommodation cavity, the semiconductor die having die pads; a protective layer, covering the semiconductor die and the carrying base; first vias in the protective layer, at the die pads; and connection terminals of conductive material. The connection terminals have first connection portions in the first vias, in electrical contact with the die pads, and second connection portions, extending on the protective layer, along a side surface of the packaged device.

### BACKGROUND

### Technical Field

The present disclosure relates to a packaged semiconductor device having improved reliability and inspectionability and the manufacturing method thereof.

### Description of the Related Art

It is known to enclose semiconductor devices comprising a single die or a plurality of reciprocally coupled dice in a housing or package of insulating material, typically of resin or composite material. These packages may be configured differently, according to the intended type of mounting. Furthermore, in case the device is designed to work at high voltage and/or current, these packages usually comprise structures capable of dissipating heat on one or more sides.

### BRIEF SUMMARY

The present disclosure provides a package which overcomes the drawbacks of the prior art.

According to the present disclosure, a packaged electronic device and the manufacturing method thereof are provided.

In at least one embodiment, a packaged device includes a front surface, a back surface opposite to the front surface, and a side surface extending between the front surface and the back surface; a carrying base; an accommodation cavity in the carrying base; a semiconductor die in the accommodation cavity, the semiconductor die having die pads; a protective layer, covering the semiconductor die and the carrying base; first vias in the protective layer, at the die pads; and connection terminals of conductive material, the connection terminals having first connection portions in the first vias, in electrical contact with the die pads, and second connection portions, extending on the protective layer, along the side surface of the packaged device; a support having conductive contact regions facing the first connection portions of the connection terminals; and adhesive regions between the conductive contact regions and the front surface of the device, in electrical contact with the connection terminals, the adhesive regions further extending along the side surface of the packaged device, in contact with the second connection portions, of the connection terminals.

### BRIEF DESCRIPTION OF THE SEVERAL VIEWS OF THE DRAWINGS

For a better understanding of the present disclosure, embodiments thereof are now described, purely by way of non-limiting example, with reference to the accompanying drawings, wherein:

FIGS. 1-10 are cross-sections of a comparative example device during successive packaging steps;

FIG. 11 is a lateral view of the comparative example device of FIG. 10;

FIG. 12 is an enlarged scale cross-section, similar to FIGS. 1-10, of a portion of the comparative example device of FIG. 10;

FIGS. 13-21 are cross-sections of the present device during successive steps of the present packaging method, according to an embodiment;

FIG. 22 is a top view of the intermediate structure of FIG. 14;

FIGS. 23 and 24 show top views of portions of the intermediate structure of FIG. 20, according to two different embodiments;

FIG. 25 is a lateral view of the present packaged device, after soldering to a board;

FIG. 26 is an enlarged scale cross-section of a portion of the device of FIG. 25, taken along section line XXVI-XXVI of FIG. 25; and

FIG. 27 shows a variation of the cross-section of FIG. 26.

### DETAILED DESCRIPTION

Hereinafter, reference will be made to packages providing dual side cooling, for surface mounting, having input/output (I/O) pads arranged on the bottom side of the device.

For example, US 2017/0148746 (U.S. Pat. No. 10,083,888) describes different surface mounting package structures, designed to reduce the risk of die/dice breakdown during lamination of the housing material. In these known package structures, a conductive base, typically of metal, has a cavity accommodating a die and a protective layer passed by conductive vias.

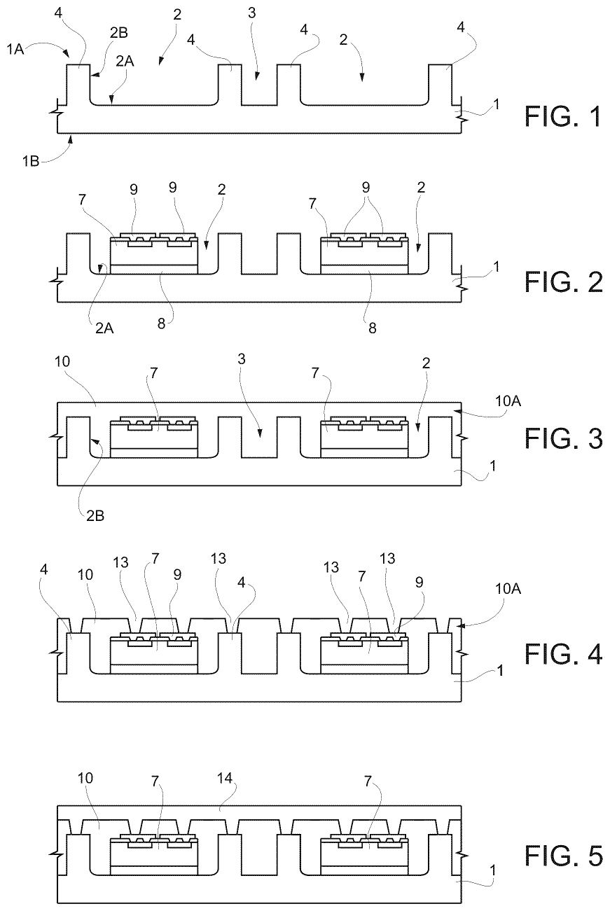

A package structure of the type described in the aforementioned patent may be formed, for example, using the process shown in FIGS. 1-10 and described hereinafter.

FIG. 1 shows a conductive base 1 of metal, such as copper or other metal or metal alloy, having a top surface 1A and a bottom surface 1B.

The top surface 1A is shaped and has a plurality of accommodation cavities 2, surrounded by a separation cavity 3. The accommodation cavities 2 may have a substantially parallelepiped shape, with a bottom surface 2A connected to side walls 2B. The side walls 2B are defined by projections 4 of the conductive base 1.

The conductive base 1 may be formed, for example, from a metal band, processed to remove the metal in the cavities 2 and 3.

With reference to FIG. 2, dice 7 are bonded to the accommodation cavities 2 through conductive adhesive regions 8, for example of a conductive gel or an epoxy layer.

The dice 7 may integrate single power components or integrated circuits including power components, processing components and electrical connections, schematically shown in the figures and connected to the outside by pads 9 arranged on the front side of the dice 7.

The dice 7 are bonded to the bottom surface 2A of the respective accommodation cavity 2 on their back side.

Subsequently, FIG. 3, a protective layer 10 is deposited on the conductive base 1 and on the dice 7, for example using a lamination technique. The protective layer 10 is, for example, of polyamide (so-called prepeg). The protective layer 10 is deposited in a fluid state so as to penetrate into the accommodation cavities 2, between the side walls 2B and the dice 7, as well as within the separation cavity 3, and completely covers the dice 7 with a portion 10A extending above the accommodation cavities 2A.

In FIG. 4, vias 13 are formed in the protective layer 10, for example by laser drill, possibly after covering the protective layer 10 through a thin anti-reflective layer (not shown), for example of copper. The vias 13 extend for the entire thickness of the portion 10A of the protective layer 10 up to the pads 9 which are thus exposed. Furthermore, the vias 13 are also formed on the projections 4.

In FIG. 5, a conductive layer 14 is formed on the protective layer 10 and fills the vias 13. The conductive layer 14 may be of copper or an alloy thereof.

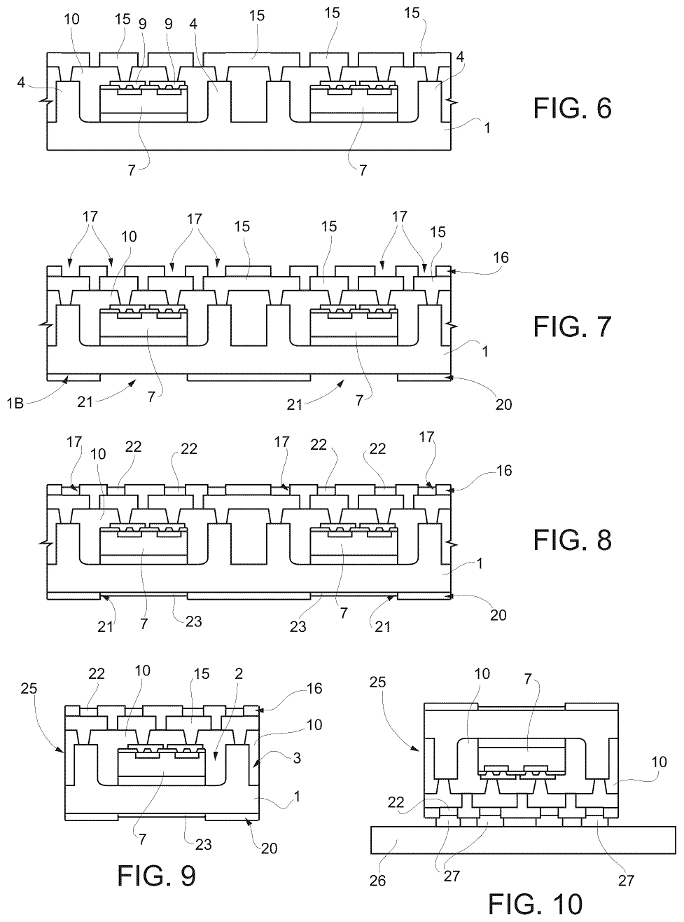

In FIG. 6, the conductive layer 14 is patterned, for example by etching, to form connection regions 15, each in electrical contact with a respective pad 9 or with the respective projection 4 of the conductive base 1.

In FIG. 7, a first insulating layer 16, for example an insulating alloy or solder, is formed and shaped above and between the connection regions 15. The first insulating layer 16 has first openings 17 at the connection regions 15.

Furthermore, a second insulating layer 20 is formed and shaped on the bottom surface 1B of the conductive base 1. The second insulating layer 20 has second openings 21, for example one for each die 7, underlying the respective die 7.

In FIG. 8, top outer pads 22 are formed in the first openings 17 of the first insulating layer 16 and bottom outer pads 23 are formed in the second openings 21 on the bottom surface 1B of the conductive base 1. The outer pads 22 and 23 are of electrically conductive material and are formed, for example, through an ENIG (Electroless Nickel Immersion Gold) process, that is by galvanic nickel growth and formation of a thin gold layer obtained by immersion, to improve the possibility of soldering and the non-oxidability.

The connection regions 15 and the top outer pads 22 form top terminals of the device; the bottom outer pads 23 form bottom terminals as well as thermal dissipation surfaces of the devices (not yet separated).

In a not-shown manner, connection elements, such as solder balls, not shown, may be formed on the outer pads 22 and 23.

Hereinafter, FIG. 9, the conductive base 1 is cut along scribe lines passing through the protective layer 10 arranged in the separation cavity 3, forming single packaged devices 25 (one shown). For example, in FIG. 9, the packaged device 25 comprises a single die 7 arranged in an own accommodation cavity 2.

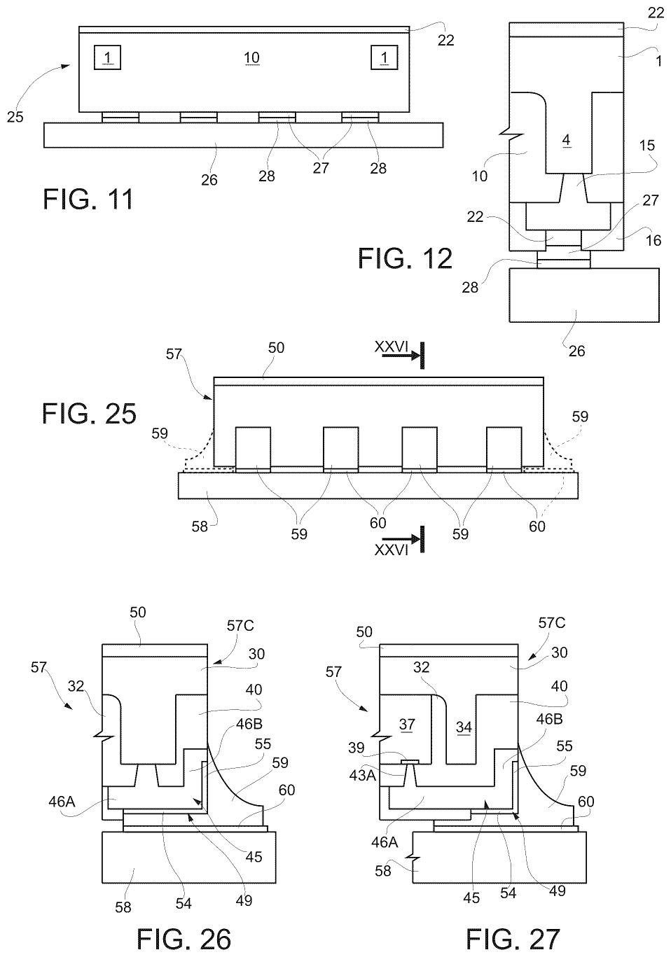

In FIG. 10, the packaged device 25 is flipped over and bonded to a board 26, for example of a printed circuit, through solder zones 27 of conductive material, such as solder, applied at the top outer pads 22 and soldered to contacts 28 formed on the board 26 (see also the lateral view of FIG. 11 and the enlarged cross-section of FIG. 12).

Returning to FIG. 10, the bottom outer pad 23 remains here exposed and may be used for the electrical connection of the conductive base 1, in a not-shown manner.

The package shown in FIGS. 11 and 12 provides good protection and high dissipation, but may be improved.

In fact, it does not allow a simple inspection of the solder zones 27 which electrically connect the front outer pads 23 to the board 26, since they are arranged hidden under the device 25, as may be seen from FIGS. 11 and 12. Consequently, their integrity may not be ensured, reducing the Board Level Reliability (BLR).

On the other hand, more and more applications, such as automotive, have high reliability and quality requirements, which are not obtainable with the described packaging.

FIG. 13 shows a carrying base 30, typically of metal, such as copper or other metal or alloy, having a top surface 30A and a bottom surface 30B.

The top surface 30A is shaped and has a plurality of accommodation cavities 32, surrounded by a separation cavity 33.

The separation cavity 33 has, for example, a grid shape and extends along first lines passing through the drawing plane (parallel to a first axis Y of a Cartesian reference system XYZ) and along second lines parallel to a second axis X of the Cartesian reference system XYZ.

The accommodation cavities 32 may have a substantially parallelepiped, cubic, generally polyhedral or even cylindrical shape, provided with a bottom surface 32A connected to side walls 32B. The side walls 32B are formed by projections 34 of the carrying base 30.

The carrying base 30 may be formed, for example, from a metal band, which is processed to remove the metal in the cavities 32 and 33.

With reference to FIG. 14, dice 37 are bonded to the accommodation cavities 32 through conductive adhesive regions 38, for example of a conductive gel or an epoxy layer.

The dice 37 may integrate single power components or integrated circuits including power components, processing components and electrical connections, schematically shown in the figures and connected to the outside through die pads 39 arranged on the front side of the dice 37.

The dice 37 are bonded to the bottom surface 32A of the respective accommodation cavity 32 with their back side.

Subsequently, FIG. 15, a protective layer 40 is deposited on the carrying base 30 and on the dice 37, for example by using a lamination technique. The protective layer 40 is, for example, of polyamide (so-called prepeg). The protective layer 40 is deposited in a fluid state so as to penetrate into the accommodation cavities 32, between the side walls 2B and the dice 37, as well as within the separation cavity 33 (where it forms a filling portion 35 having the grid shape of the separation cavity 33). The protective layer 40 also completely covers the dice 37 with a covering portion 40A extending above the accommodation cavities 32A and the filling portion 35.

The covering portion 40A of the protective layer 40 may have a thickness comprised between 100 and 150 μm.

In FIG. 16, first and second vias 43A, 43B are formed through the covering portion 40A of the protective layer 40, for example by laser drill, possibly after covering the protective layer 40 through a thin anti-reflective layer (not shown), for example of copper. The first vias 43A extend along the whole thickness of the covering portion 40A of the protective layer 10 up to the die pads 39, which are thus exposed; the second vias 43B extend on the projections 34 of the carrying base 30.

Furthermore, grooves 41 are formed in the filling portion 35 of the separation cavity 33. The grooves 41 may have depths equal to the vias 43A, 43B (as shown in FIG. 16) or different depth, typically greater, up to half the thickness of the carrying base 30 or even more if desired. For example, according to the package type, they may have depths of at least 100 μm, typically 150-200 μm, but they may reach 350 μm in the case of 700 μm-thick packages. However, they may also have a smaller thickness, e.g., 75-95 μm, in the case of standard MLP/QFN packages.

The grooves 41 also have a minimum width of 100 μm or, in any case, so that they may be coated in the successive plating step, as described hereinafter with reference to FIG. 17, without being filled.

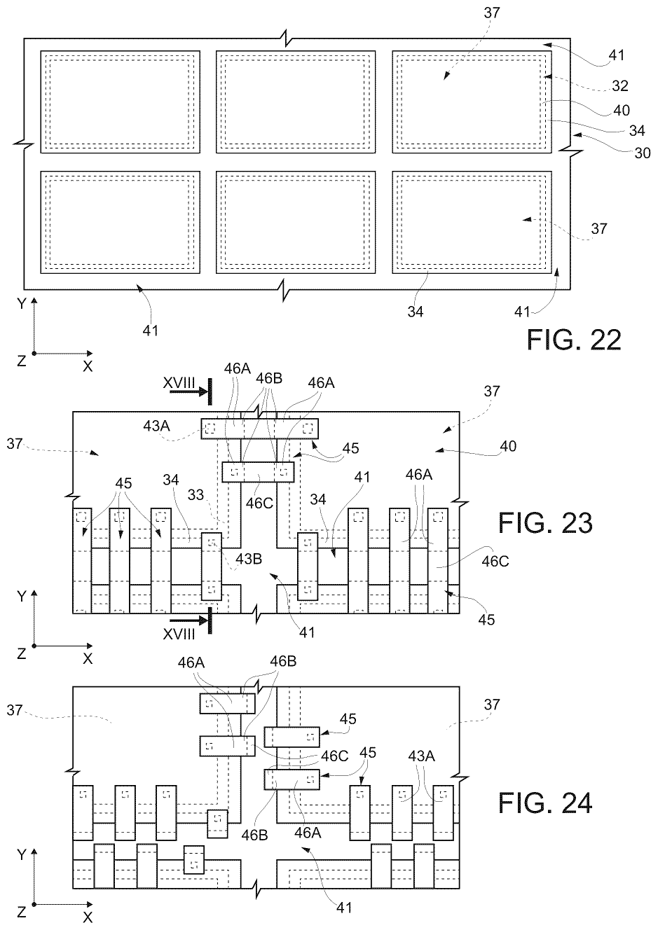

The grooves 41 may be formed by laser ablation, by blade/saw surface cutting, by shallow dicing or even by etching, in predetermined positions, at the vias 43A, 43B (hereinafter generically referred to as vias 43, if it is not necessary to distinguish them) or along the lines of the separation cavity 33, as shown in FIG. 22 (practically forming a single grid-shaped groove).

When the grooves 41 are formed by laser ablation or etching, they may be formed simultaneously with the vias 43.

The grooves 41 may have vertical walls, in particular when formed by blade/saw cutting, or slightly inclined walls (2-3°), if formed by laser ablation.

If the grooves 41 are formed by blade/saw cutting, they have non-perfectly smooth walls, which may be useful in helping sticking in the successive plating step (as described hereinafter with reference to FIG. 17).

In FIG. 17, a conductive layer 44 is formed on the protective layer 40 and fills the vias 43. The conductive layer 44 also coats the bottom and flanks of the grooves 41. The conductive layer 44 may be of copper or an alloy thereof and have a thickness of 35-70 μm, also according to the width of the grooves 41, and may be galvanically deposited (copper plating).

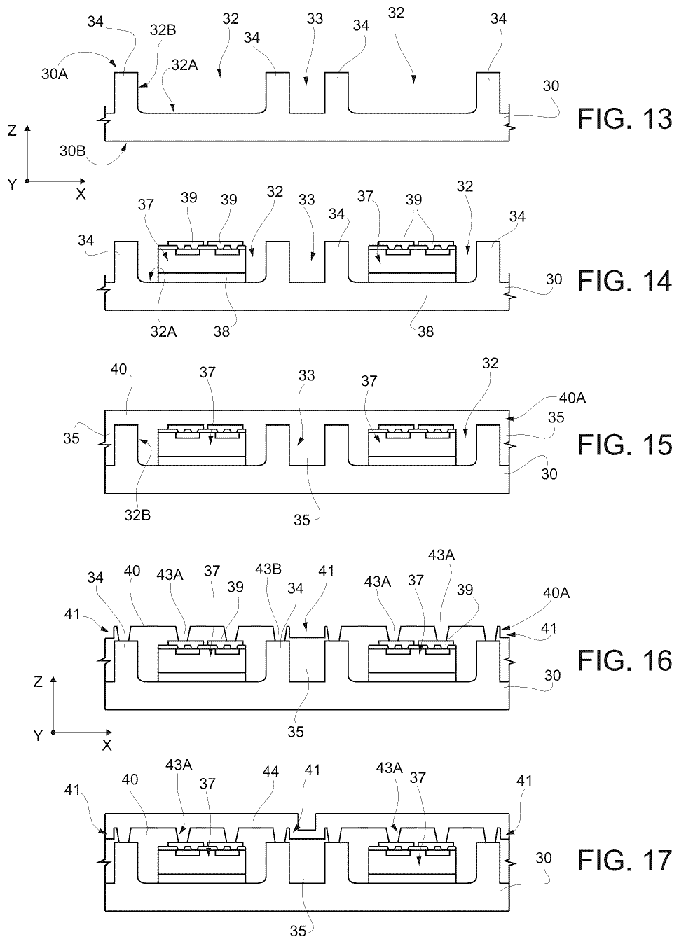

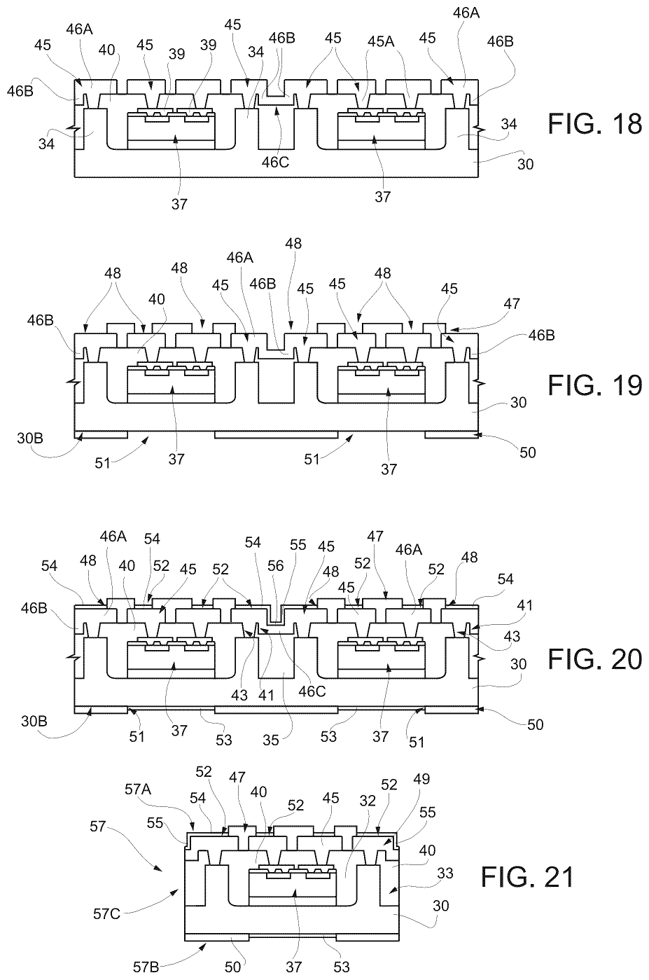

In FIG. 18, the conductive layer 44 is defined or patterned, for example by etching, to form connection regions 45 for the electrical connection of the die pads 39 and of the carrying base 30.

Each connection region 45 has a connecting portion 45A extending in a respective via 43; a surface portion 46A, extending above the protective layer 40, and a vertical portion 46B, extending on the flank of the adjacent groove 41.

In FIG. 19, a first insulating layer 47, for example an alloy or an insulating solder, is formed above the intermediate structure of FIG. 18. The first insulating layer 47 is then patterned, so as to have first openings 48 at the connection regions 45.

Furthermore, a second insulating layer 50 is formed and patterned on the bottom surface 30B of the carrying base 30. The second insulating layer 50 has second openings 51, for example one for each die 37, underlying the respective die 37.

In general, the first and the second insulating layers 47, 50 are of the same material and may be deposited and patterned in two different steps.

In FIG. 20, front outer connections are formed in the first openings 48 of the first insulating layer 50, on the connection regions 45; and back outer connections 53 are formed in the second openings 51 on the bottom surface 30B of the carrying base 30. The back outer connections 53 also form thermal dissipation surfaces.

In particular, in FIG. 20, the front outer connections 52 have top portions 54 extending on the front side of the dice 37, directly on the surface portions 46A of the connection regions 45; side portions 55 extending on the vertical portions 46B of the connection regions 45; and bottom portions 56 extending on the bottom sections 46C of the connection regions 45.

The outer connections 52 and 53 are of high electrical conductivity material and are, for example, formed through ENIG (Electroless Nickel Immersion Gold) process, that is by galvanic growth of nickel and formation of a thin gold layer obtained by immersion.

In this step, the vertical portions 46B and the side portions 55, facing each other, of two different dice 37, may still be connected to each other through the bottom sections 46C and the bottom portions 56 at the bottom of the groove 41 (e.g., as shown in FIG. 23) and are subsequently separated during the cutting step, as explained hereinafter.

Alternatively, as shown in FIG. 24, the vertical portions 46B and the side portions 55, facing each other, of different dice 37, may be separated from each other, with smaller bottom sections 46C and bottom portions 56 that are not connected in pairs.

Hereinafter, FIG. 21, the intermediate structure of FIG. 20 is cut along scribe lines passing through the filling portions 35 of the protective layer 40, forming single packaged devices 57 (one shown). For example, in FIG. 21, the packaged device 57 comprises a single die 37 arranged in an own accommodation cavity 32.

In practice, the scribe lines pass through the bottom portions 56 of the front outer pads 52, removing them almost completely and the side portions 55 of the front outer connections 52 are exposed along the side of the packaged device 57.

Following the cut, each packaged device 57 has a front surface 57A, a back surface 57B, opposite to the front surface, and a side surface 57C extending between the front surface and the back surface.

In this manner, after cutting, the connection regions 45 and the front outer connections 52 form I/O terminals 49 of the packaged devices 57. In particular, the I/O terminals 49 are formed by first connection portions in the vias 43, in electrical contact with the die pads 39 (formed by the connecting portions 45A of the connection regions 45); by second connection portions, comprising the vertical portions 46B of the connection regions 45 and the side portions 55 of the front outer connections 52 extending above the protective layer 40, along the side surface 57C of the packaged device 57; and by third connection portions, comprising the surface portions 46A of the connection regions 45 and the top portions 54 of the front outer connections 52, extending above the protective layer 40, along the front surface 57A of the packaged device 57.

Remarkably, the shape of the surface portions 46A of the connection regions 45 and the top portions 54 of the front outer connections 52 is designed to electrically connect the die pads 39 and the projections 34 according to the desired configuration, in a manner that is obvious to a person skilled in the art. For example, FIG. 27 shows an embodiment where the front outer connections 52 do not extend above the first vias 43A.

Then, FIG. 25, the packaged device 57 is flipped over and bonded to a board 58, for example of a printed circuit. To this end, the board 58 has contacts 60 arranged at the I/O terminals 49 and precisely at the top portions 54 of the front outer connections 52; and solder regions 59 of conductive material, e.g., solder, have been previously applied to the contacts 60 on the board 58 or to the I/O terminals 49. The solder regions 59 may be applied by screen printing and heat treatment, according to techniques known to the person skilled in the art.

In particular, as visible in the cross-section of FIG. 26, in the packaged device 57 the solder regions 59 may adhere both to the top portions 54 and to the side portions 55 of the front outer connections 52.

Consequently, the packaged device 57 has a wettable flank package, as desired in some applications wherein high Board Level Reliability (BLR) of the soldering is desired, for example in the automotive field.

In fact, in this manner, the solder area considerably increases; furthermore, the side portions 55 of the front outer connections 52 are optically inspectable in a simple manner, both by human operators and automatically, allowing the solder integrity to be easily verified (reliable and inspectable meniscus).

These advantages are all the more evident as deeper are the grooves 41 and thus the greater is the height of the side portions 55 of the front outer connections 52 (and of the respective underlying vertical portions 46B of the connection regions 45) which, as said, may reach half the thickness of the carrying base 30 (as a first approximation, equal to the thickness of the packaged device 57).

Furthermore, the packaged device 57 thus obtained has comparable and only slightly higher manufacturing costs with respect to known devices, since it includes only one additional operating step, for forming the grooves 41.

Finally, it is clear that modifications and variations may be made to the packaged device and to the manufacturing method described and illustrated herein without thereby departing from the scope of the present disclosure, as defined in the attached claims.

For example, each accommodation cavity 32 may contain more than one die 37.

A packaged device (57) having a front surface (57A), a back surface (57B), opposite to the front surface, and a side surface (57C) extending between the front surface and the back surface, may be summarized as including: a carrying base (30); an accommodation cavity (32) in the carrying base; a semiconductor die (37) in the accommodation cavity (32), the semiconductor die having die pads (39); a protective layer (40), covering the semiconductor die and the carrying base; first vias (43A) in the protective layer, at the die pads (39); and connection terminals (49) of conductive material, the connection terminals having first connection portions (45A) in the first vias (43A), in electrical contact with the die pads (39), and second connection portions (46B, 55), extending on the protective layer (40), along the side surface (57C) of the packaged device.

The carrying base (30) may be of conductive material and may have delimitation walls (34) of the accommodation cavity (32), the device comprising second vias (43B) extending in the protective layer (40) at the delimitation walls (34) of the carrying base (30) and base connection terminals (49) having first base connection portions (45A) extending in the second vias, in electrical contact with the carrying base, and second base connection portions (46A, 46B, 54, 55), extending above the protective layer (40) and along the side surface (57C) of the packaged device (57).

The front surface (57A) and the back surface (57B) of the packaged device (57) may be arranged at a distance along a device height direction and the second connection portions (54, 55) of the connection terminals (49) may have a length, in the height direction, lower than the distance between the front surface (57A) and the back surface (57B) of the packaged device.

The carrying base (30) may have a height in the device height direction, and the second connection portions (54, 55) of the connection terminals (49) may have, in the device height direction, a length equal to half the height of the carrying base (30). The connection terminals (49) may include third connection portions (46A, 54) extending above the protective layer (40), along the front surface (57A) of the packaged device (57), between the first and the second connection portions.

The first connection portions (45A) of the connection terminals (49) may be of a first material; the second connection portions (46B, 55) of the connection terminals may include vertical portions (46B) of the first material, extending adjacent to the side surface (57C) of the packaged device (57), and side portions (55) of a second material, extending above the vertical portions (46B), along the side surface of the packaged device; and the third connection portions (46A, 54) of the connection terminals may include surface portions (46A), of the first material, extending above the protective layer (40) between the first connection portions (45A) and the vertical portions (46B), and top portions (54), of the second material, extending above the surface portions (46A).

A first insulating layer (47) may extend between and partially above the surface portions (46A) and may have openings (48) wherein the top portions (54) of the connection terminals (49) extend.

An electronic device may be summarized as including: the packaged device (57); a support (58) having conductive contact regions (60) facing the first connection portions (45A) of the connection terminals; and adhesive regions (59) between the conductive contact regions (60) and the front surface (57A) of the device, in electrical contact with the connection terminals (49), the adhesive regions (59) further extending along the side surface (57C) of the packaged device, in contact with the second connection portions (46B), (55) of the connection terminals.

A method for manufacturing a packaged device may be summarized as including the steps of: forming a carrying base (30) having a plurality of accommodation cavities (32) surrounded by delimitation walls accommodating a separation cavity (33); bonding a plurality of semiconductor dice (37) into the accommodation cavities (32), the semiconductor dice having die pads (39); forming a protective layer (40) above the semiconductor dice and the carrying base, the protective layer extending in the accommodation cavities (32) around the semiconductor dice and in the separation cavity (33); forming first vias (43A) in the protective layer (40) at the die pads (39); forming grooves (41) in the protective layer (40), above the separation cavity (33); forming connection terminals of conductive material, the connection terminals having first connection portions (45A) in the first vias (43A), in electrical contact with the dice (37), and second connection portions (46B, 55) in the grooves; and cutting the carrying base and the protective layer (40) at the grooves (41) thereby separating a plurality of packaged devices (57), each packaged device having a side surface (57C), and exposing the second connection portions (46B, 55) along the side surface of each packaged device.

Forming connection terminals (49) may include: depositing a conductive layer (44) of a first conductive material on the protective layer, thereby forming the first connection portions (45A) in the first vias, the vertical portions (46B) in the grooves, surface portions (46A) between the first connection portions (45A) and the vertical portions (46B), as well as bottom sections (46C) on bottom surfaces of the grooves (41); forming insulating regions (47) between and partially above the surface portions (46A), the insulating regions (47) having openings (48); and forming outer connection regions of a second conductive material in the openings (48), the outer connection regions comprising top portions (54) on the surface portions (46A), side portions (55) on the vertical portions (46B) and bottom portions (56) on the bottom sections (46C).

Cutting the carrying base (30) and the protective layer (40) may include removing the bottom sections (46C) of the conductive layer (44) and the bottom portions (56).

The carrying base (30) may have a height and the grooves (41) may have a maximum depth equal to half the height of the carrying base.

The carrying base (30) may be of conductive material, the method may further include: forming second vias in the protective layer (40) at the delimitation walls (34) of the carrying base; and forming base connection terminals (49), of conductive material, within the second vias (43B) and in the grooves (41), above the protective layer (40), wherein cutting the carrying base (30) and the protective layer (40) may include exposing the base connection terminals along the side surface (57C) of each packaged device (57).

Forming the grooves (41) may include laser ablation, or blade/saw cutting or etching.

The method for manufacturing an electronic device may include bonding the packaged device (57) to a support (58) having conductive contact regions (60), wherein bonding may include applying adhesive regions (59) between the conductive contact regions (60) and the first connection portions (45A) and on a side surface of the packaged device (57), in contact with the second connection portions (46B), (55) of the connection terminals (49).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for manufacturing a packaged device, comprising:
forming a carrying base having a plurality of accommodation cavities surrounded by delimitation walls accommodating a separation cavity;
bonding a plurality of semiconductor dice into the accommodation cavities, the semiconductor dice having die pads;
forming a protective layer above the semiconductor dice and the carrying base, the protective layer extending in the accommodation cavities around the semiconductor dice and in the separation cavity;
forming first vias in the protective layer at the die pads;
forming grooves in the protective layer, above the separation cavity;
forming connection terminals of conductive material, the connection terminals having first connection portions in the first vias, in electrical contact with the dice, and second connection portions in the grooves; and
cutting the carrying base and the protective layer at the grooves thereby separating a plurality of packaged devices, each packaged device having a side surface, and exposing the second connection portions along the side surface of each packaged device.

2. The method according to claim 1, wherein forming connection terminals comprises:
depositing a conductive layer of a first conductive material on the protective layer, thereby forming the first connection portions in the first vias, the vertical portions in the grooves, surface portions between the first connection portions and the vertical portions, as well as bottom sections on bottom surfaces of the grooves;
forming insulating regions between and partially above the surface portions, the insulating regions having openings; and
forming outer connection regions of a second conductive material in the openings, the outer connection regions comprising top portions on the surface portions, side portions on the vertical portions and bottom portions on the bottom sections.

3. The method according to claim 2, wherein cutting the carrying base and the protective layer comprises removing the bottom sections of the conductive layer and the bottom portions.

4. The method according to claim 2, wherein the carrying base has a height and the grooves have a maximum depth equal to half the height of the carrying base.

5. The method according to claim 1, wherein the carrying base is of conductive material, the method further comprising:
forming second vias in the protective layer at the delimitation walls of the carrying base; and
forming base connection terminals, of conductive material, within the second vias and in the grooves, above the protective layer,
wherein cutting the carrying base and the protective layer comprises exposing the base connection terminals along the side surface of each packaged device.

6. The method according to claim 5, wherein forming the grooves comprises laser ablation, or blade/saw cutting or etching.

7. The method according to claim 1, further comprising bonding at least one of the packaged devices to a support having conductive contact regions, wherein bonding comprises applying adhesive regions between the conductive contact regions and the first connection portions and on a side surface of the at least one of the packaged devices, in contact with the second connection portions, of the connection terminals.

8. A method for manufacturing a packaged device, comprising:
coupling a first die to a carrying base within a first accommodation cavity of the carrying base;
coupling a second die to a carrying base within a second accommodation cavity of the carrying base spaced apart from the first accommodation cavity, and the second accommodation cavity is separated from the first accommodation cavity by a plurality of projections of the carrying base that delimit and define a separation cavity between the first accommodation cavity and the second accommodation cavity;
forming a protective layer within the first accommodation cavity, within the second accommodation cavity, within the separation cavity, covering the first die, covering the second die, and covering the plurality of projections;
forming a plurality of first vias extending into the protective layer to a plurality of first electrical contacts of the first die and a plurality of second electrical contacts of the second die;
forming a plurality of second vias extending into the protective layer to a plurality of end surfaces of the plurality of projections;
forming a groove extending into the protective layer and aligned with the separation cavity and defining one or more walls of the protective layer that delimit and define the groove;
forming a conductive layer in the plurality of first vias, on the plurality of first electrical contacts, on the plurality of second electrical contacts, in the groove, on the one or more walls, and on the protective layer;
forming a plurality of first connections regions coupled to the first electrical contacts and the second electrical contacts and forming a second connection region coupled to the plurality of end surfaces of the plurality of projection regions and within the groove by patterning the conductive layer;
forming a first insulating layer on the plurality of first connection regions and on the second connection region;
forming a plurality of first openings extending into the first insulating layer to the plurality of first connection regions and the second connection region by patterning the first insulating layer;
forming a first conductive material on the plurality of first connection regions and on the second connection region through the plurality of first openings; and
cutting along a scribe line passing through and along the separation cavity of the carrying base, cutting along the scribe line cuts the first conductive material on the second connection region, the second connection region, the protective layer, and the carrying base.

9. The method of claim 8, wherein forming the conductive layer in the groove further includes forming a recess extending into the conductive layer aligned with the groove.

10. The method of claim 9, wherein forming the first conductive material on the second connection region further includes forming the first conductive material within the recess and lining the recess with the first conductive material.

11. The method of claim 10, wherein the scribe line is aligned with and extends through the recess.

12. The method of claim 11, wherein cutting along the scribe line defines side portions of the first conductive material by cutting the first conductive material on the second connection region.

13. The method of claim 7, further comprising forming a second insulating layer on a surface of the carrying base that is opposite to and faces away from the first accommodation cavity, the second accommodation cavity, and the separation cavity of the carrying base.

14. The method of claim 13, further comprising:
forming a plurality of second openings in the second insulating layer by patterning the second insulating layer, the plurality of second openings extend through the second insulating layer to the surface of the carrying base; and
forming a second conductive material on the surface of the carrying base and within the plurality of second openings.

15. The method of claim 14, wherein forming the plurality of second openings further includes forming each respective second openings of the plurality of second openings to be aligned with a corresponding die of the first die and the second die.

16. The method of claim 7, wherein cutting along the scribe line passing through and along the separation cavity of the carrying base further includes defining a packaged device with side connection regions exposed along side surfaces of the packaged device, and the side connection regions includes exposed surfaces of the first conductive material and the second connection region.

17. The method of claim 16, further comprising bonding the packaged device utilizing the side connection regions and a solder material to a contact of a board.

18. A method, comprising:
forming a plurality of first vias extending into the protective layer to a plurality of first electrical contacts of the first die and a plurality of second electrical contacts of the second die;
forming a plurality of second vias extending into the protective layer to a plurality of end surfaces of the plurality of projections;
forming a groove extending into the protective layer and aligned with the separation cavity and defining one or more walls of the protective layer that delimit and define the groove;
forming a conductive layer in the plurality of first vias, on the plurality of first electrical contacts, on the plurality of second electrical contacts, in the groove, on the one or more walls, and on the protective layer;
forming a plurality of first connections regions coupled to the first electrical contacts and the second electrical contacts and forming a second connection region coupled to the plurality of end surfaces of the plurality of projection regions and within the groove by patterning the conductive layer;
forming a first insulating layer on the plurality of first connection regions and on the second connection region;
forming a plurality of first openings extending into the first insulating layer to the plurality of first connection regions and the second connection region by patterning the first insulating layer;
forming a first conductive material on the plurality of first connection regions and on the second connection region through the plurality of first openings; and
cutting along a scribe line passing through and along the separation cavity of the carrying base, cutting along the scribe line cuts the first conductive material on the second connection region, the second connection region, the protective layer, and the carrying base, and cutting along the scribe line defines at least one packaged device and defines side connection regions of the packaged device including respective side surfaces of the first conductive material and the second connection region being exposed along a sidewall of the packaged device.

19. The method of claim 17, wherein forming the groove includes laser ablation, blade/saw cutting, or etching.

20. The method of claim 17, further comprising:
forming a second insulating layer on a surface of the carrying base that is opposite to and faces away from the first accommodation cavity, the second accommodation cavity, and the separation cavity of the carrying base;
forming a plurality of second openings in the second insulating layer by patterning the second insulating layer, the plurality of second openings extend through the second insulating layer to the surface of the carrying base;
forming a second conductive material on the surface of the carrying base and within the plurality of second openings; and
forming the plurality of second openings further includes forming each respective second openings of the plurality of second openings to be aligned with a corresponding die of the first die and the second die.
